(19) United States
(12) Patent Application Publication
(10) Pub. No.: US 2025/0176159 A1
(43) Pub. Date: May 29, 2025

(54) SEMICONDUCTOR DEVICE AND METHOD OF FORMING THE SAME

(71) Applicant: NANYA TECHNOLOGY CORPORATION, New Taipei city (TW)

(72) Inventors: Ying-Cheng CHUANG, Taoyuan City (TW); Yu-Ting LIN, New Taipei City (TW)

(21) Appl. No.: 18/523,109

(22) Filed: Nov. 29, 2023

(51) Int. Cl. H10B 12/00

(52) U.S. Cl. CPC H10B 12/053; H10B 12/34

(57) ABSTRACT

A semiconductor device includes a substrate, an active region in the substrate, and a gate structure in the active region. The gate structure includes a bottom conductive layer, a top conductive layer on the bottom conductive layer, and a cap layer on the top conductive layer. A width of the bottom conductive layer is wider than a width of the top conductive layer, and a width of the cap layer is wider than the width of the top conductive layer. The top conductive layer and the bottom conductive layer are made of a same material. A method of forming the semiconductor device is also disclosed.

### BACKGROUND

### Field of Invention

The present invention relates to a semiconductor device and a method of forming the same.

### Description of Related Art

In recent decades, demand to storage capability has increased as electronic products continue to improve. In order to increase storage capability of a memory device (e.g., a DRAM device), more memory cells are integrated in the memory device. As the integration level increases, fabrication process of the memory device become much more complicated, and process window become rather narrow.

### SUMMARY

An aspect of the disclosure provides a semiconductor device. The semiconductor device includes a substrate, an active region in the substrate, and a gate structure in the active region. The gate structure includes a bottom conductive layer, a top conductive layer on the bottom conductive layer, and a cap layer on the top conductive layer. A width of the bottom conductive layer is wider than a width of the top conductive layer, and a width of the cap layer is wider than the width of the top conductive layer. The top conductive layer and the bottom conductive layer are made of a same material.

In some embodiments, a work function of the top conductive layer is identical to a work function of the bottom conductive layer.

In some embodiments, the material of the bottom conductive layer and the top conductive layer includes titanium nitride.

In some embodiments, a material of the cap layer includes silicon nitride.

In some embodiments, an interface is present between the bottom conductive layer and the top conductive layer.

In some embodiments, the semiconductor device further includes a lining layer surrounding the bottom conductive layer, and a passivation layer surrounding the top conductive layer, wherein a thickness of the passivation layer is thicker than a thickness of the lining layer.

In some embodiments, the semiconductor device further includes a passivation layer surrounding the top conductive layer, and a barrier layer surrounding the cap layer. A thickness of the passivation layer is thicker than a thickness of the cap layer.

In some embodiments, the semiconductor device further includes an isolation region in the substrate, and a dummy gate structure in the isolation region, wherein the dummy gate structure extends deeper than the gate structure in the substrate.

In some embodiments, the isolation region includes an oxide layer directly in contact with the active region and a nitride layer sandwiched by the oxide layer.

Another aspect of the disclosure provides a method of forming a semiconductor device. The method includes forming an active region in a substrate; forming a trench in the active region; depositing a lining layer in the trench; depositing a conductive material to fill the trench; etching back the conductive material and the lining layer to form a bottom conductive layer in the trench; and forming a top conductive layer on the bottom conductive layer. A width of the bottom conductive layer is wider than a width of the top conductive layer, and the top conductive layer and the bottom conductive layer are made of a same material.

In some embodiments, the top conductive layer is directly in contact with the bottom conductive layer, and an interface is present between the top conductive layer and the bottom conductive layer.

In some embodiments, a thin portion of the lining layer is remained on a sidewall of the trench after etching back the conductive material and the lining layer.

In some embodiments, forming the top conductive layer on the bottom conductive layer includes depositing a passivation layer on the bottom conductive layer and on a sidewall of the trench; removing a lateral portion of the passivation layer to expose a top surface of the bottom conductive layer; depositing an additional conductive material to fill the trench; and etching back the additional conductive material and the passivation layer such that the top conductive layer is formed on the bottom conductive layer.

In some embodiments, a thickness of the passivation layer is thicker than a thickness of the lining layer.

In some embodiments, an edge of the top surface of the bottom conductive layer is covered by the passivation layer.

In some embodiments, a thin portion of the passivation layer is remained on the sidewall of the trench after etching back the additional conductive material and the passivation layer.

In some embodiments, the method further includes depositing a barrier layer on the top conductive layer and on the sidewall of the trench; removing a lateral portion of the barrier layer to expose a top surface of the top conductive layer; depositing a cap material to fill the trench and above the substrate; and removing a portion of the cap material to form a cap layer on the top conductive layer.

In some embodiments, a width of the cap layer is wider than the width of the top conductive layer.

In some embodiments, a thickness of the passivation layer is thicker than a thickness of the barrier layer.

In some embodiments, removing the portion of the cap material comprises performing a planarization process.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 is a schematic layout of a semiconductor device according to some embodiments of the disclosure; and

FIGS. 2-14 are cross-sectional views of different steps of a method of forming a semiconductor device, taken along line A-A in FIG. 1, according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

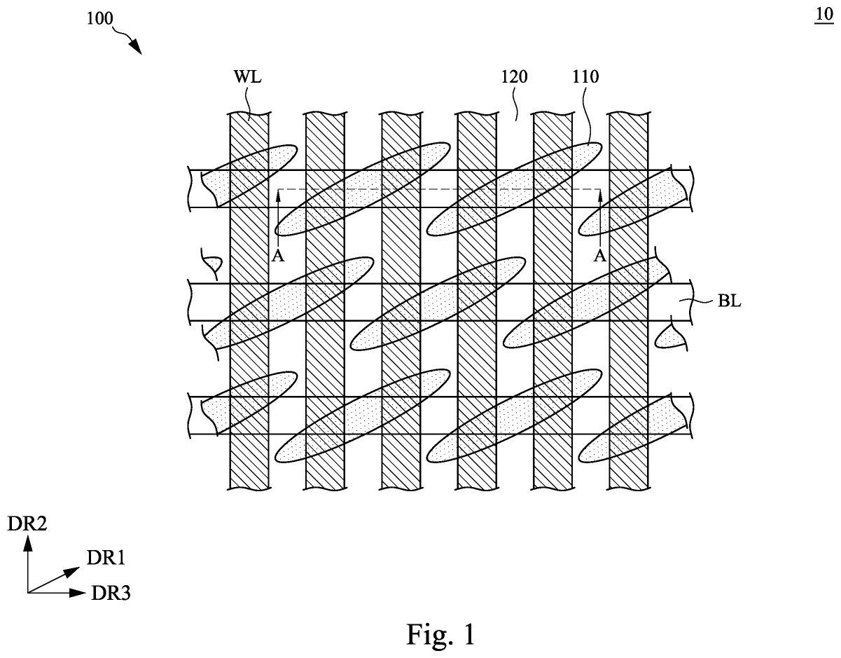

FIG. 1 is a schematic layout of a semiconductor device according to some embodiments of the disclosure. A dynamic random access memory (DRAM) array 10 is shown as an example of the semiconductor device 100 according to some embodiments of the disclosure. The semiconductor device 100 includes a plurality of active regions 110 that are defined by an isolation region 120 formed in a substrate. The active regions 110 may extend in a first direction DR1, a plurality of word lines WLs extend in a second direction DR2 which forms an angle with the first direction DR1, and a plurality of bit lines BLs extend in a third direction DR3 which forms an angle with the first direction DR1. In some embodiments, the shape of the active regions 110 can be an ellipse. The angle between the first direction DR1 and the second direction DR2 and the angle between the first direction DR1 and the third direction DR3 may be, but are not limited to, 45 and 45 degrees, 30 and 60 degrees, or 60 and 30 degrees, respectively. In some embodiments, the word lines WLs are formed perpendicular to the bit lines BLs. That is, the angle between the second direction DR2 and the third direction DR3 may be 90 degrees.

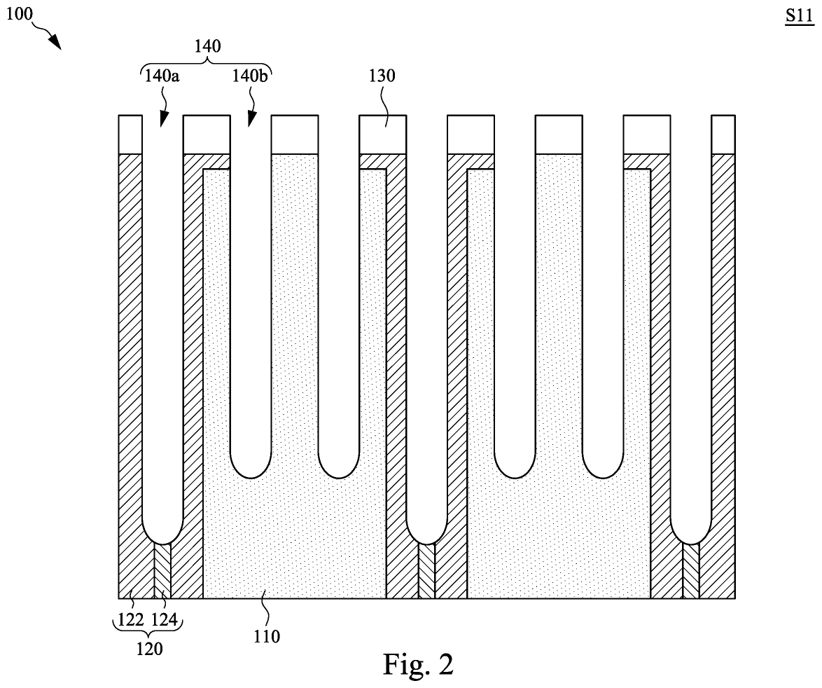

Reference is made to FIGS. 2-14, which are cross-sectional views of different steps of a method of forming a semiconductor device, taken along line A-A in FIG. 1, according to some embodiments of the disclosure. As shown in FIG. 2, the method begins at step S11. The semiconductor device 100 includes the active regions 110 defined by the isolation region 120. In some embodiments, the active regions 110 and the isolation region 120 are formed in the substrate, in which the substrate may be, for example, a silicon (Si) substrate. Alternatively, the substrate can be a Si substrate and is doped with other semiconductor materials. In some other embodiments, the substrate may include a layered semiconductor such as silicon/silicon germanium, silicon-on-insulator, or silicon germanium-on-insulator. In some embodiments, the active regions 110 may be doped with an N-type dopant such as phosphorus (P), arsenic (As), or antimony (Sb). In some other embodiments, the active regions 110 may be doped with a P-type dopant such as boron (B) or indium (In). In some embodiments, the substrate may be or include an unimplanted area. In some embodiments, the active regions 110 may have a higher doping concentration than the substrate.

The isolation region 120 is formed surrounding the active regions 110 to separate the active regions 110 from other. In some embodiments, the isolation region 120 is a multi-layer structure including an oxide layer 122 directly in contact with the active regions 110 and a nitride layer 124 sandwiched by the oxide layer 122. The multi-layer structure ensures a seamless isolation region 120 and provides better electrical isolation between the active regions 110.

A pattered hard mask layer 130 having a plurality of openings is formed on the substrate, and an etching process is performed through the openings to form plurality of trenches 140 in the active regions 110 and in the isolation region 120. In some embodiments, the trenches 140 are formed by performing a wet etching process or a dry etching process. Due to the etching selectivity of materials of the active regions 110 and the isolation region 120, the depth of the trenches 140 such as trenches 140a in the isolation region 120 is deeper than the trenches 140 such as trenches 140b in the active regions 110, and portions of the nitride layer 124 of the isolation region 120 is revealed from the trenches 140a.

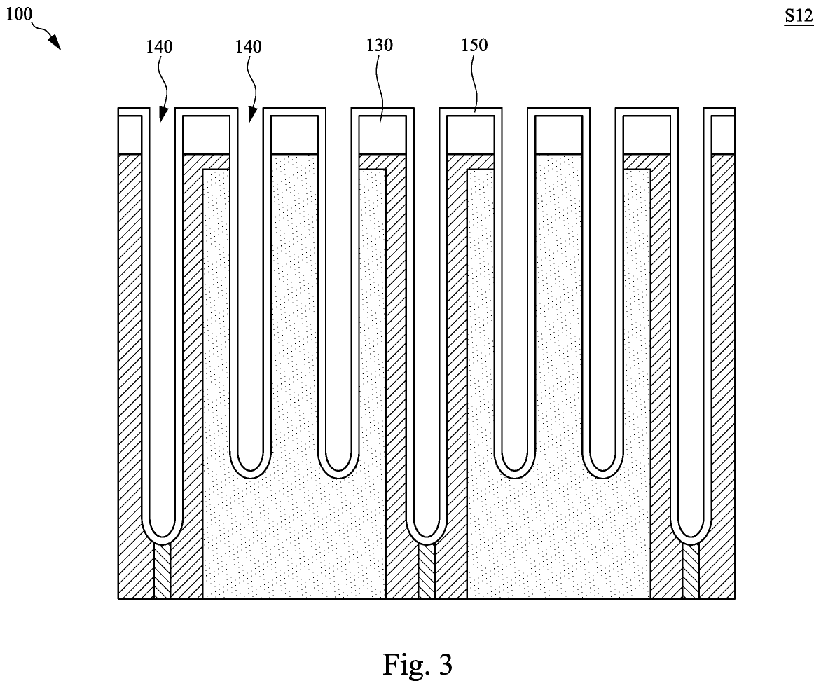

Reference is made to FIG. 3. As shown in step S12, a lining layer 150 is formed on sidewalls of the trenches 140 and on the hard mask layer 130. In some embodiments, the lining layer 150 is an oxide layer and is formed by an atomic layer deposition process such that the lining layer 150 is conformally formed on sidewalls of the trenches 140 and on the hard mask layer 130.

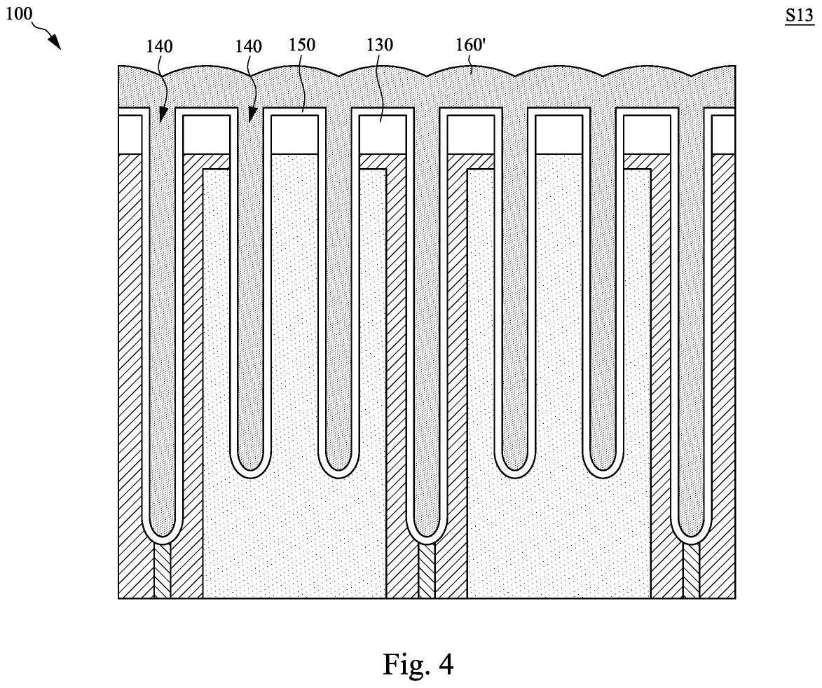

Reference is made to FIG. 4. As shown in step S13, a conductive material 160′ is deposited and fills the trenches 140. In some embodiments, the conductive material 160′ not only fills the trenches 140 but also covers the hard mask layer 130. In some embodiments, the conductive material 160′ can be titanium nitride or tungsten.

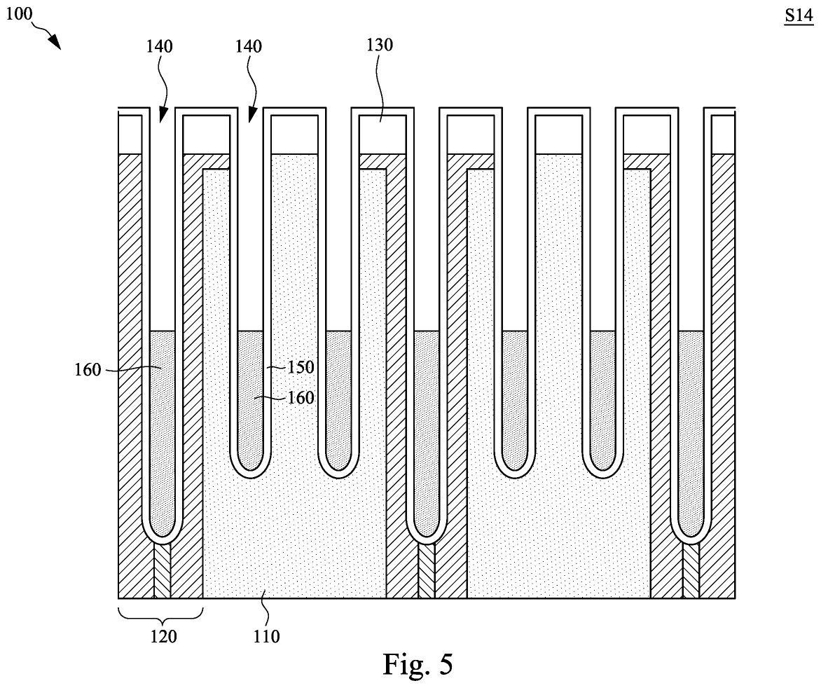

Reference is made to FIG. 5. As shown in step S14, an etch back process is performed to remove portions of the conductive material 160′ (as shown in FIG. 4) in the trenches 140 and the conductive material 160′ over the hard mask layer 130. Portions of the conductive material 160′ are remained in the bottom of the trenches 140, and the remaining portions of the conductive material 160′ can be regarded as bottom conductive layers 160 in the trenches 140. In some embodiments, the etch back process is a selective etching process which has a greater etching to the conductive material 160′ than the lining layer 150, thus the lining layer 150 is remained on the sidewalls of the trenches 140 after the etch back process is performed.

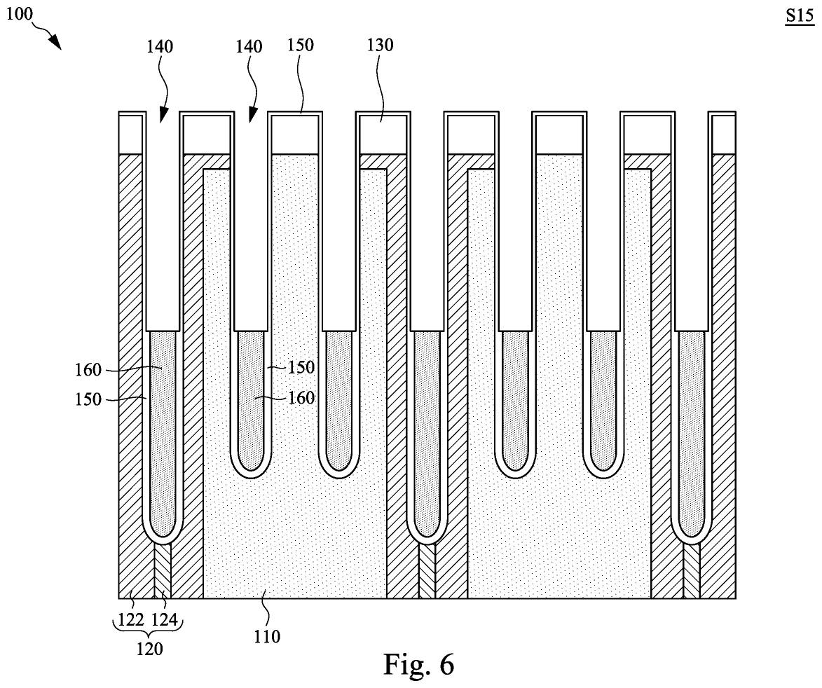

Reference is made to FIG. 6. As shown in step S15, a cleaning process is performed to remove residues of the conductive material 160′, and portions of the lining layer 150 above the bottom conductive layers 160 are removed during the cleaning process. The cleaning process can be a wet cleaning process, including using dilute HF as an etchant. The portions of the lining layer 150 at the bottom of the trenches 140 are sandwiches between the bottom conductive layers 160 and the active regions 110 or between the bottom conductive layers 160 and the isolation region 120.

In some embodiments, the lining layer 150 at top sections of the trenches 140 is not completely removed after the cleaning process is performed. Therefore, the sidewalls of the active regions 110 can be protected by the remaining thin lining layer 150, and thus the loss of the active regions 110 can be prevented. In some other embodiments, the lining layer 150 at top sections of the trenches 140 is completely removed after the cleaning process is performed, and the sidewalls of the active regions 110 are exposed.

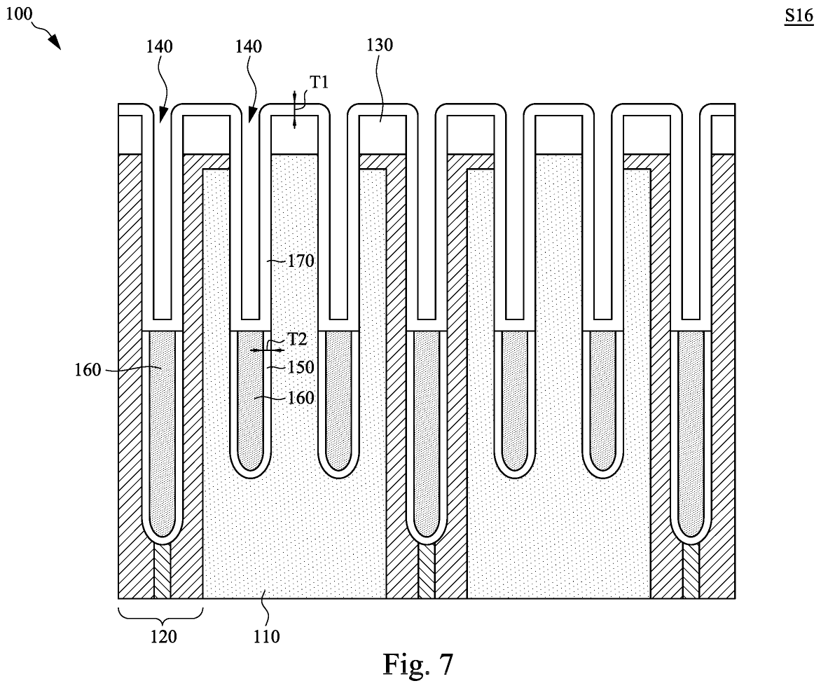

Reference is made to FIG. 7. As shown in step S16, a passivation layer 170 is formed on the hard mask layer 130, the trenches 140, and top surfaces of the bottom conductive layers 160. In some embodiments, the passivation layer 170 is formed by an atomic layer deposition process such that the passivation layer 170 is conformally formed on the hard mask layer 130, the sidewalls of the trenches 140, and the top surfaces of the bottom conductive layers 160. In some embodiments, the passivation layer 170 is an oxide layer, and the thickness T1 of the passivation layer 170 is thicker than the thickness T2 of the lining layer 150. The trenches 140 are not completely filled by the passivation layer 170. In some embodiments, the passivation layer 170 includes the remaining thin lining layer 150, if exists.

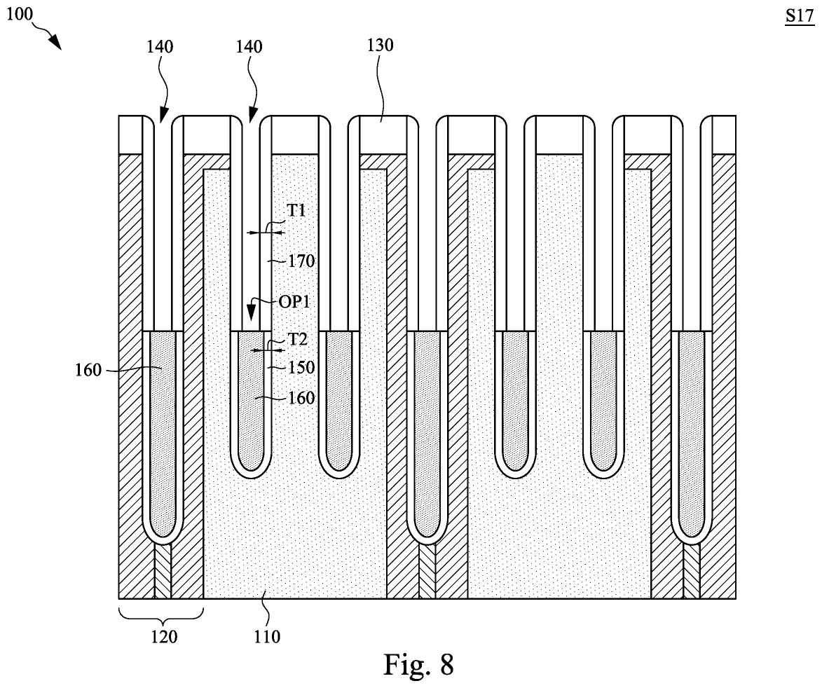

Reference is made to FIG. 8. As shown in step S17, a directional etching process is performed to remove lateral portions of the passivation layer 170, and the vertical portions of the passivation layer 170 are remained on sidewalls of the trenches 140. Therefore, openings OP1 are formed at the bottom of the passivation layer 170 after the directional etching process is performed, and the top surfaces of the bottom conductive layers 160 are exposed by openings OP1 of the passivation layer 170. Because the thickness of the T1 of the passivation layer 170 is thicker than the thickness T2 of the lining layer 150, edges of the bottom conductive layers 160 are covered by the remained vertical portions of the passivation layer 170.

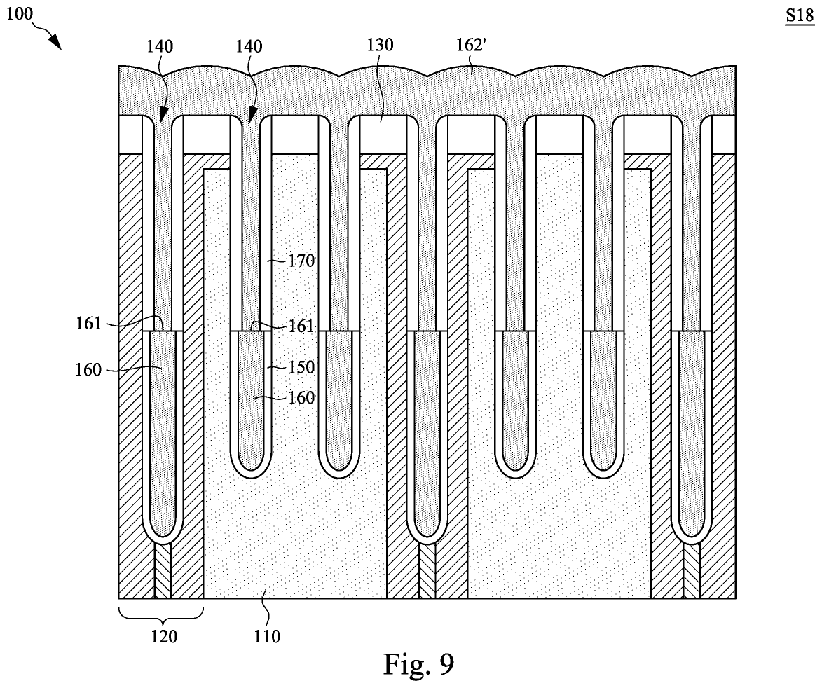

Reference is made to FIG. 9. As shown in step S18, an additional conductive material 162′ is deposited filling the trenches 140 and over the hard mask layer 130. The gap between the vertical portions of the passivation layer 170 is filled by the additional conductive material 162′, and the additional conductive material 162′ is connected to the bottom conductive layers 160. In some embodiments, the material of the additional conductive material 162′ can be the same as the material of the bottom conductive layers 160, such as titanium nitride or tungsten. In some embodiments, an interface 161 is present between the additional conductive material 162′ and the bottom conductive layers 160.

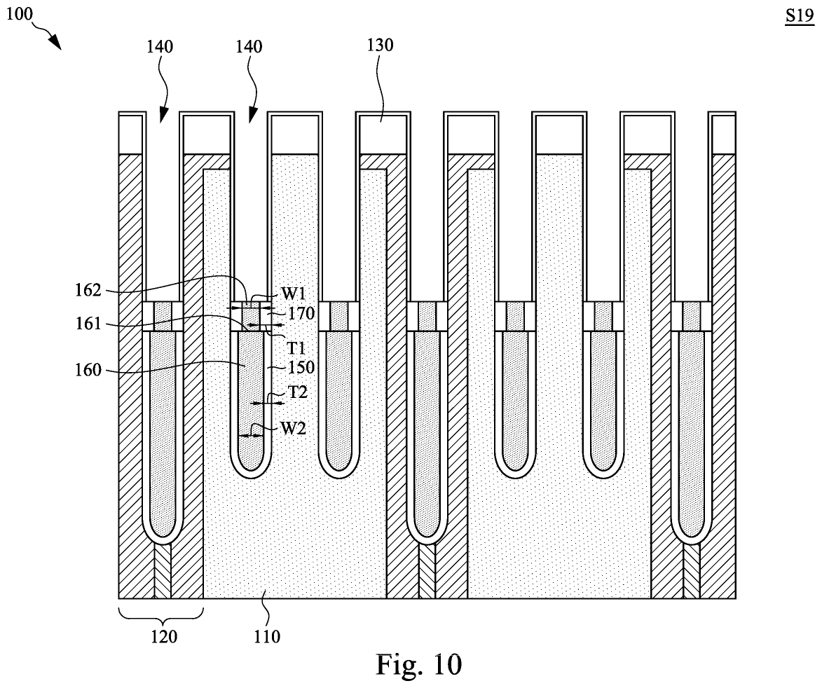

Reference is made to FIG. 10. As shown in step S19, an etch back process is performed to remove portions of the conductive material 162′ (as shown in FIG. 9) and the passivation layer 170 from top sections of the trenches 140 and over the hard mask layer 130, and portions of the additional conductive material 162′ and the passivation layer 170 at middle sections of the trenches 140 are remained on the bottom conductive layers 160.

As a result, portions of the additional conductive material 162′ are disposed on the bottom conductive layers 160 and can be regarded as top conductive layers 162, and the top conductive layers 162 are surrounded by the passivation layer 170, respectively. In some embodiments, the thickness of the T1 of the passivation layer 170 is thicker than the thickness T2 of the lining layer 150, and the width W1 of each of the top conductive layers 162 is narrower than the width W2 of each of bottom conductive layers 160. In some embodiments, the interface 161 is present between each of the top conductive layers 162 and each of bottom conductive layers 160. In some embodiments, the material of the top conductive layers 162 is the same as the material of the bottom conductive layers 160, thus the work function of the top conductive layers 162 is identical to the work function of the bottom conductive layers 160.

In some embodiments, the passivation layer 170 at top sections of the trenches 140 is not completely removed while the additional conductive material 162′ at top sections of the trenches 140 is completely removed. Therefore, the sidewalls of the active regions 110 can be protected by the remaining thin passivation layer 170 during the etch back process, and thus the loss of the active regions 110 can be prevented. In some other embodiments, the passivation layer 170 at top sections of the trenches 140 can be completely removed, and the sidewalls of the active regions are exposed.

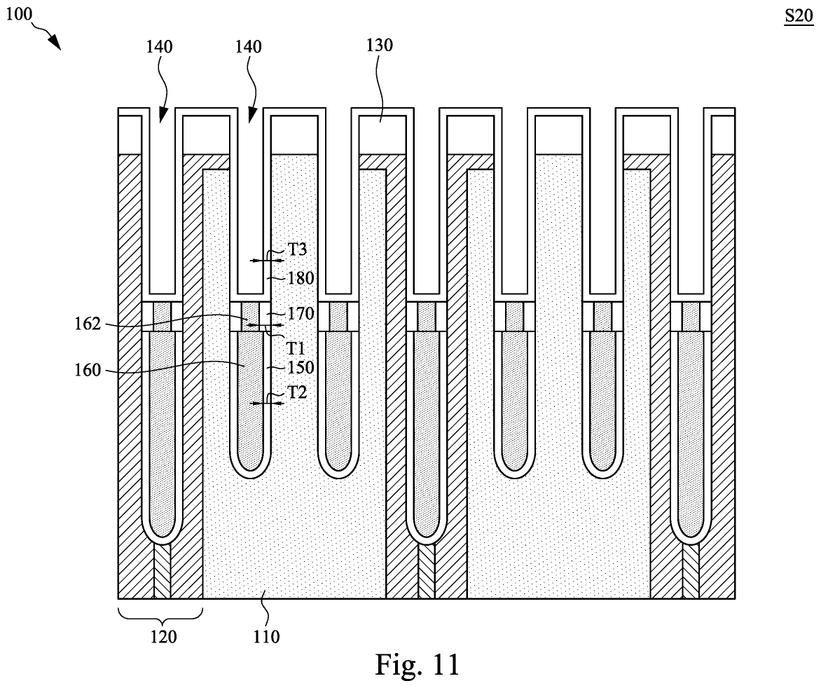

Reference is made to FIG. 11. As shown in step S20, a barrier layer 180 is formed on the hard mask layer 130, the sidewalls of the trenches 140, and the top surfaces of the top conductive layers 162 and the passivation layer 170. In some embodiments, the barrier layer 180 is formed by an atomic layer deposition process such that the barrier layer 180 is conformally formed on the hard mask layer 130, the sidewalls of the trenches 140, and the top surfaces of the top conductive layers 162 and the passivation layer 170. In some embodiments, the barrier layer 180 is an oxide layer. In some embodiments, the thickness T3 of the barrier layer 180 is thinner than the thickness T1 of the passivation layer 170. In some embodiments, the barrier layer 180 includes the remaining thin passivation layer 170, if exists.

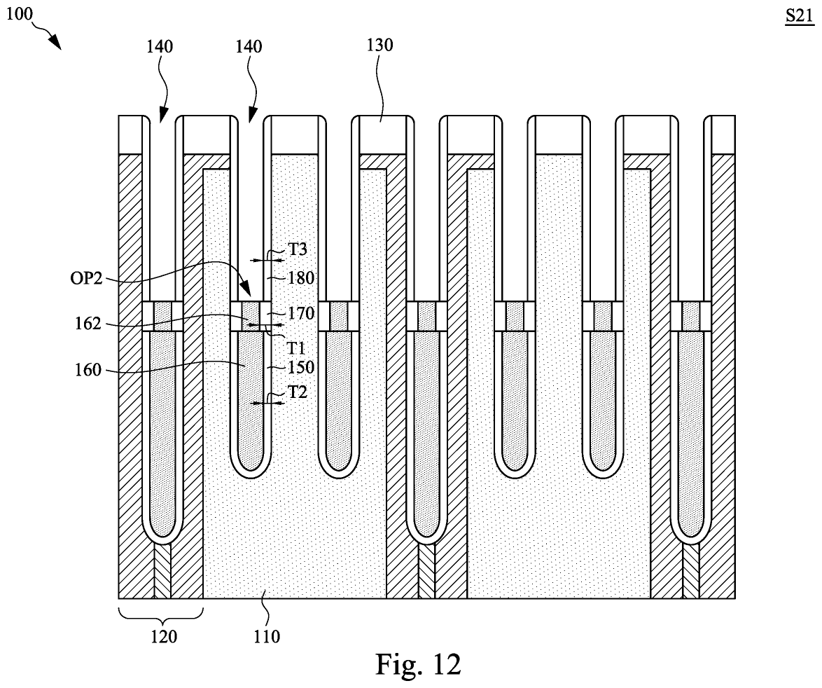

Reference is made to FIG. 12. As shown in step S21, a directional etching process is performed to remove lateral portions of the barrier layer 180, and the vertical portions of the barrier layer 180 are remained on sidewalls of the trenches 140. Therefore, openings OP2 are formed at the bottom of the barrier layer 180 after the directional etching process is performed, and the top surfaces of the top conductive layers 162 are exposed by the openings OP2 of the barrier layer 180. Because the thickness T3 of the barrier layer 180 is thinner than the T1 of the passivation layer 170, portions of the top surface of the passivation layer 170 are also exposed by the openings OP2 of the barrier layer 180.

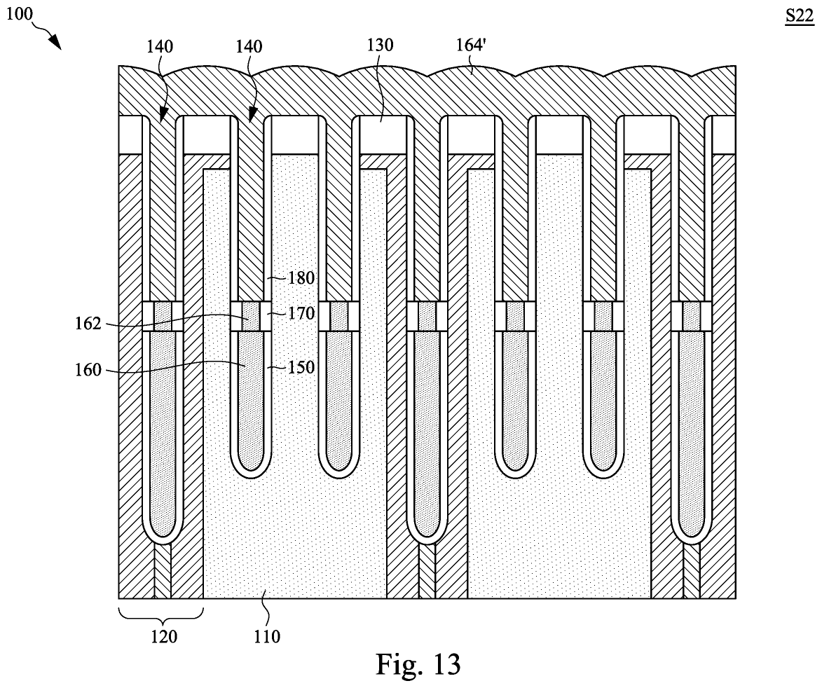

Reference is made to FIG. 13. As shown in step S22, a cap material 164′ is deposited filling the top sections of the trenches 140 and above the hard mask layer 130. The cap material 164′ is deposited on the top conductive layers 162 and the passivation layer 170, through the openings OP2 of the barrier layer 180 (as shown in FIG. 12). The cap material 164′ for example can be a nitride such as silicon nitride.

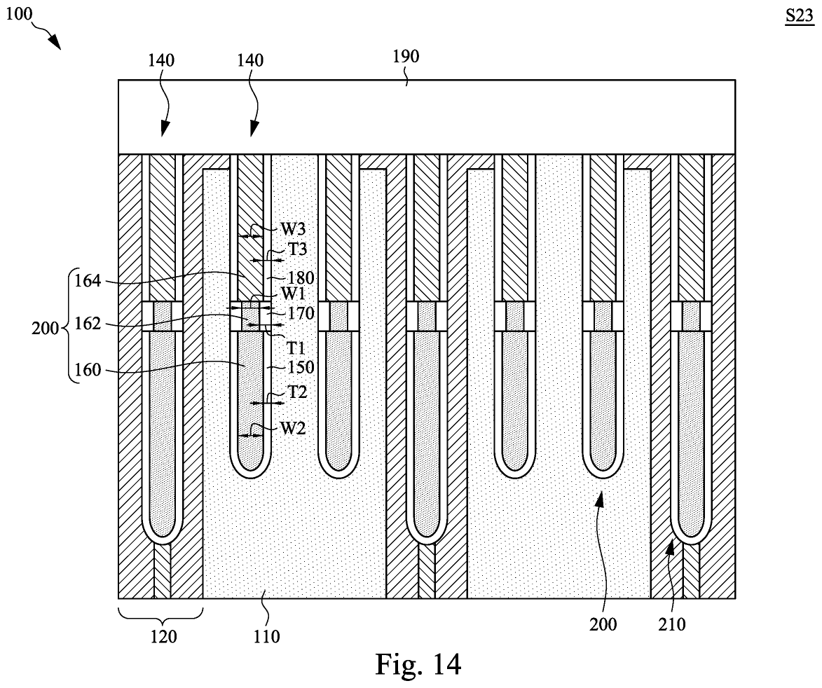

Reference is made to FIG. 14. As shown in step S23, a planarization process is performed to remove the hard mask layer 130 (as shown in FIG. 13) and portions of the cap material 164′ (as shown in FIG. 13) to expose the active regions 110 and the isolation region 120 again. The remaining cap material 164′ in the trenches 140 can be regarded as cap layers 164 in the trenches 140. The width W3 of each of the cap layers 164 is wider than the width W1 of each of the top conductive layers 162. The top surfaces of the active regions 110, the isolation region 120, the cap layers 164, and the barrier layer 180 are coplanar after the planarization process is performed. Then a dielectric layer 190 is formed on the top surfaces of the active regions 110, the isolation region 120, the cap layers 164, and the barrier layer 180.

Please refer to both FIG. 1 and FIG. 14. The semiconductor device 100 including the active regions 110, the isolation region 120, and the word lines WLs is provided. Each of the word lines WLs has a plurality of segments in the active regions 110, as the gate structures 200, and a plurality of segments in the isolation region 120, as the dummy gate structures 210. In some embodiments, the dummy gate structures 210 extend deeper than the gate structures 200.

Each of the gate structures 200 includes the bottom conductive layer 160 surrounded by the lining layer 150, the top conductive layer 162 on the bottom conductive layer 160 and surrounded by the passivation layer 170, and the cap layer 164 on the top conductive layer 162 and surrounded by the barrier layer 180. In some embodiments, the thickness T1 of the passivation layer 170 is thicker than the thickness T2 of the lining layer 150, and the thickness T1 of the passivation layer 170 is thicker than the thickness T3 of the barrier layer 180. Accordingly, the width W3 of the cap layer 164 is wider than the width W1 of the top conductive layer 162, and the width W2 of the bottom conductive layer 160 is wider than the width W1 of the top conductive layer 162. Namely, the top conductive layer 162 has a reduced width in the gate structure 200.

In some embodiments, the top conductive layer 162 and the bottom conductive layer 160 are made of the same material such as titanium nitride or tungsten, and thus the word line WL has a single work function. The lining layer 150 and the passivation layer 170 at the gate structure 200 can be together regarded as a gate dielectric layer. In some embodiments, the lining layer 150 in the dummy gate structure 210 can be thicker than the lining layer 150 in the gate structure 200.

In each of the gate structure 200, the bottom conductive layer 160 and the top conductive layer 162 are made of the same conductive material thus the resistance (R) of the single work function gate structure 200 is relative lower than dual or multiple work function gate structure. The bottom conductive layer 160 is surrounded by the thinner lining layer 150 which can increase the resistive current between the drain and the source (Ids). The top conductive layer 162 is surrounded by the thicker passivation layer 170 which is benefit to improve gate induced drain leakage (GIDL).

It will be apparent to those skilled in the art that various modifications and variations can be made to the structure of the present invention without departing from the scope or spirit of the disclosure. In view of the foregoing, it is intended that the present invention cover modifications and variations of this invention provided they fall within the scope of the following claims and their equivalents.

What is claimed is:

1. A semiconductor device, comprising:
a substrate;
an active region in the substrate; and
a gate structure in the active region, the gate structure comprising a bottom conductive layer, a top conductive layer on the bottom conductive layer, and a cap layer on the top conductive layer, wherein a width of the bottom conductive layer is wider than a width of the top conductive layer, and a width of the cap layer is wider than the width of the top conductive layer, wherein the top conductive layer and the bottom conductive layer are made of a same material.

2. The semiconductor device of claim 1, wherein a work function of the top conductive layer is identical to a work function of the bottom conductive layer.

3. The semiconductor device of claim 1, wherein the material of the bottom conductive layer and the top conductive layer comprises titanium nitride.

4. The semiconductor device of claim 1, wherein a material of the cap layer comprises silicon nitride.

5. The semiconductor device of claim 1, wherein an interface is present between the bottom conductive layer and the top conductive layer.

6. The semiconductor device of claim 1, further comprising:
a lining layer surrounding the bottom conductive layer; and
a passivation layer surrounding the top conductive layer, wherein a thickness of the passivation layer is thicker than a thickness of the lining layer.

7. The semiconductor device of claim 1, further comprising:
a passivation layer surrounding the top conductive layer; and
a barrier layer surrounding the cap layer, wherein a thickness of the passivation layer is thicker than a thickness of the barrier layer.

8. The semiconductor device of claim 1, further comprising:
an isolation region in the substrate; and
a dummy gate structure in the isolation region, wherein the dummy gate structure extends deeper than the gate structure in the substrate.

9. The semiconductor device of claim 8, wherein the isolation region comprises an oxide layer directly in contact with the active region and a nitride layer sandwiched by the oxide layer.

10. A method of forming a semiconductor device, the method comprising:
forming an active region in a substrate;
forming a trench in the active region;
depositing a lining layer in the trench;
depositing a conductive material to fill the trench;
etching back the conductive material and the lining layer to form a bottom conductive layer in the trench; and
forming a top conductive layer on the bottom conductive layer, wherein a width of the bottom conductive layer is wider than a width of the top conductive layer, and the top conductive layer and the bottom conductive layer are made of a same material.

11. The method of claim 10, wherein the top conductive layer is directly in contact with the bottom conductive layer, and an interface is present between the top conductive layer and the bottom conductive layer.

12. The method of claim 10, wherein a thin portion of the lining layer is remained on a sidewall of the trench after etching back the conductive material and the lining layer.

13. The method of claim 10, wherein forming the top conductive layer on the bottom conductive layer comprises:
depositing a passivation layer on the bottom conductive layer and on a sidewall of the trench;
removing a lateral portion of the passivation layer to expose a top surface of the bottom conductive layer;
depositing an additional conductive material to fill the trench; and
etching back the additional conductive material and the passivation layer such that the top conductive layer is formed on the bottom conductive layer.

14. The method of claim 13, wherein a thickness of the passivation layer is thicker than a thickness of the lining layer.

15. The method of claim 13, wherein an edge of the top surface of the bottom conductive layer is covered by the passivation layer.

16. The method of claim 13, wherein a thin portion of the passivation layer is remained on the sidewall of the trench after etching back the additional conductive material and the passivation layer.

17. The method of claim 13, further comprising:
depositing a barrier layer on the top conductive layer and on the sidewall of the trench;
removing a lateral portion of the barrier layer to expose a top surface of the top conductive layer;
depositing a cap material to fill the trench and above the substrate; and
removing a portion of the cap material to form a cap layer on the top conductive layer.

18. The method of claim 17, wherein a width of the cap layer is wider than the width of the top conductive layer.

19. The method of claim 17, wherein a thickness of the passivation layer is thicker than a thickness of the barrier layer.

20. The method of claim 17, wherein removing the portion of the cap material comprises performing a planarization process.
